(19) United States
(12) Patent Application Publication
(10) Pub. No.: US 2016/0135283 A1
(43) Pub. Date: May 12, 2016

(54) COOLING DEVICE FOR A PRINTED CIRCUIT BOARD

(71) Applicant: VALEO SYSTEMES THERMIQUES, Le Mesnil Saint Denis (FR)

(72) Inventors: Karen Chauvin, Le Pecq (FR); Xavier Goumain, Montigny Le Bretonneux (FR); Friedbald Kiel, Fontainebleau (FR)

(73) Assignee: Valeo Systemes Thermiques, Le Mesnil Saint Denis (FR)

(21) Appl. No.: 14/653,522

(22) PCT Filed: Dec. 13, 2013
(86) PCT No.: PCT/EP2013/076501

§ 371 Date: Jun. 18, 2015

(30) Foreign Application Priority Data
Dec. 19, 2012 (FR) 1262300

(51) Int. Cl. H05K 1/02; H05K 1/18; H05K 7/20; H05K 1/11

(52) U.S. Cl. CPC H05K 1/0206; H05K 1/115; H05K 1/181; H05K 7/20863; H05K 2201/066; H05K 2201/09545

(57) ABSTRACT

The invention relates to a cooling device for a printed circuit board, comprising a printed circuit board equipped with at least one face or first face and at least one heat sink (9) brazed to said at least one face of the printed circuit, in which said at least one heat sink (9) can be disposed in a flow of coolant. The invention is suitable for motor vehicles.

The technical field of the present invention is that of an electronic printed circuit board likely to give off heat and a device for cooling said electronic component. Such a printed circuit board is notably applicable in a ventilation device intended to set in motion a flow of air in a ventilation, heating and/or air conditioning installation for a motor vehicle.

Generally, in such a printed circuit board, the cooling device takes the form of a heat dissipater, that is to say an element added onto the printed circuit board, whose function is to dissipate the heat emitted by the electronic components. This heat dissipater is pressed onto a face of the printed circuit board, a thermal conductive paste being interposed between the heat dissipater and the face of the printed circuit board so as to ensure a good heat conduction between said board and the heat dissipater.

The structure described above presents a number of drawbacks. Firstly, such a heat dissipater is a solid part which occupies a significant space, which forms a constraint which limits the possibilities of application of the printed circuit board, notably in the case of use of the printed circuit board in a confined volume, as is the case for example for a ventilation device in a ventilation, heating and/or air conditioning installation of a motor vehicle. Moreover, the weight of the known ventilation device is also burdened by the presence of this heat dissipater, the latter being made of an aluminum alloy. The heat dissipater is a part which represents a not-inconsiderable cost in the ventilation function and whose addition entails the application of a thermal paste, which increases the complexity of the printed circuit board production method. Furthermore, the presence of the thermal paste degrades the thermal heat dissipation efficiency of the heat dissipater but is nevertheless necessary to ensure the thermal diffusion between the electronic components arranged on the printed circuit board and the heat dissipater.

The aim of the present invention is to resolve the drawbacks described above.

To this end, the subject of the invention is a cooling device for a printed circuit board, comprising a printed circuit board provided with at least one face or first face and at least one heat sink element brazed onto said at least one face of the printed circuit, said at least one heat sink element being suitable for being arranged in a flow of refrigerant.

Refrigerant should be understood to mean any heat conducting fluid compatible with the printed circuit. It is, for example, air.

Thus, the cooling device according to the invention allows for a better heat dissipation by virtue of the direct physical contact of the braze between the heat sink element and the printed circuit board. Furthermore, since the heat sink element is brazed, it can be secured to the printed circuit board during a printed circuit board brazing step, which ensures that the cooling device according to the invention is produced and finalized concurrently with the production of the printed circuit board itself.

According to another feature of the invention, said printed circuit board comprises two faces.

According to another feature of the invention, the cooling device comprises at least one hole passing through said printed circuit board from one of the two faces to the other of the two faces, said at least one calorie conducting means being arranged facing said at least one through hole.

According to another feature of the invention, said at least one through hole comprises an inner surface covered with a metallic substance.

According to another feature of the invention, the cooling device comprises a plurality of holes passing through said printed circuit board.

This plurality of holes forms a thermal drain between the calories present on the first face and generated by an electronic component, and the flow of air which licks the calorie conducting means.

According to another feature of the invention, the printed circuit board is provided with an electronic component.

According to another feature of the invention, an outer perimeter of the electronic component delimits a first expropriation on the first face, the plurality of holes delimits a second expropriation on the first face, the first expropriation and the second expropriation being separated by a non-zero distance.

In other words, the electronic component is not arranged over the hole, the thermal drain between this electronic component and the hole being then made by the electrically conductive track which runs at least between these two elements.

Alternatively, the first expropriation and the second expropriation are at least partially superposed.

According to another feature of the invention, the at least one heat sink element comprises a head forming a bearing abutment against the printed circuit board.

The invention relates also to a ventilation device of a ventilation installation of a motor vehicle interior, comprising a propeller generating a flow of air and suitable for being driven by an electric motor, comprising a printed circuit board as detailed above. The printed circuit board forms a control device suitable for driving the electric motor. This control device is the means which determines the speed of rotation of the propeller, according to requests sent by the motor vehicle.

According to one possibility offered by the invention, the calorie conducting means is in direct contact with the electrically conductive track. Similarly, the heat sink is in direct contact with this calorie conducting means. Direct contact should be understood to mean a physical contact between the two elements, a securing of these elements being able to be produced by means of a braze.

A very first advantage according to the invention lies in the possibility of designing a printed circuit board that is lighter, more compact and less costly than that of the prior art, while ensuring a reliability compatible with use in the motor vehicle sector by ensuring a cooling function for the components which dissipate heat. The thermal draining is thus better ensured by virtue of the presence of the calorie conducting means which extends between the two faces of the board.

Such a printed circuit board is particularly applicable in a ventilation device for a ventilation, heating and/or air conditioning installation.

Other features, details and advantages of the invention will emerge more clearly on reading the description given hereinbelow by way of indication in relation to the drawings in which:

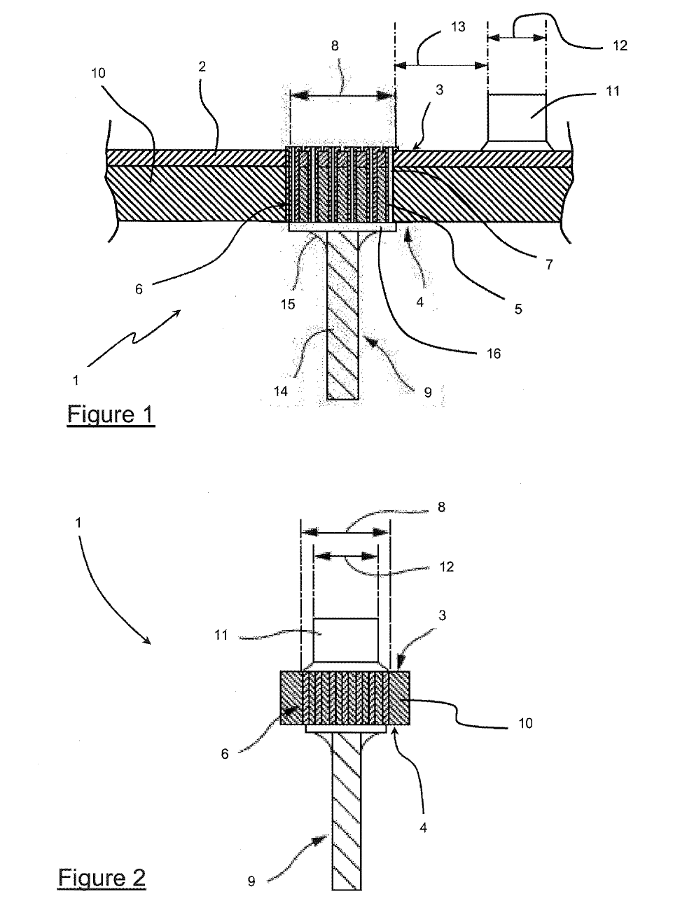

FIG. 1 is a partial cross-sectional view of a printed circuit board according to the invention,

FIG. 2 is a partial cross-sectional view illustrating a first variant embodiment of the printed circuit board according to the invention,

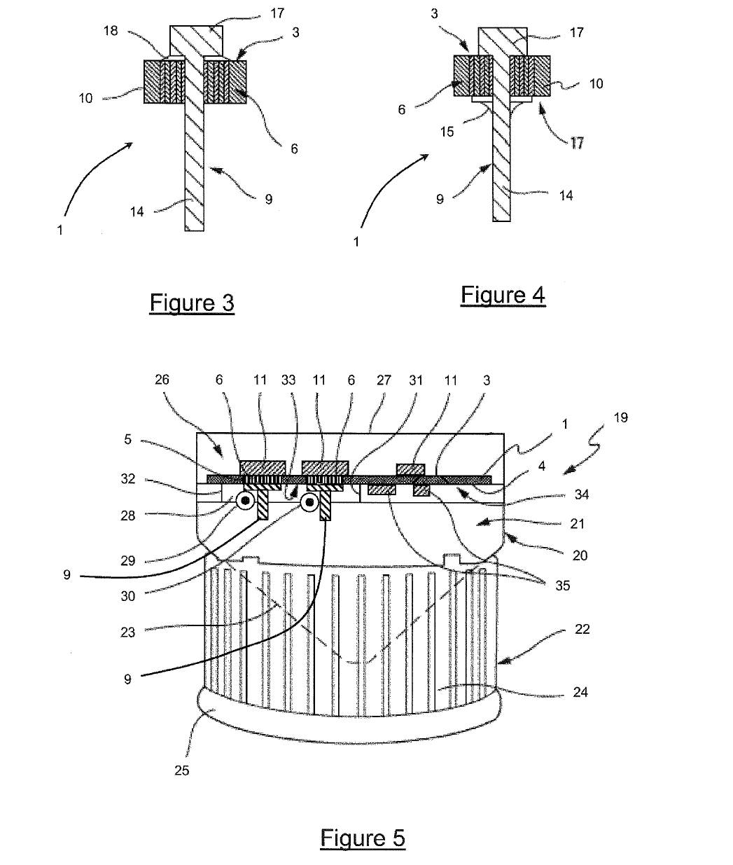

FIG. 3 is a partial cross-sectional view illustrating a second variant embodiment of the printed circuit board according to the invention,

FIG. 4 is a partial cross-sectional view illustrating a third variant embodiment of the printed circuit board according to the invention,

FIG. 5 is a schematic view of a ventilation device implementing a printed circuit board according to any one of the variants described above.

It should be noted that the figures explain the invention in a detailed manner for implementing the invention, said figures of course being able to serve to better define the invention, as appropriate.

FIG. 1 illustrates an exemplary embodiment of a cooling device comprising a printed circuit board 1 conforming to the invention. The latter is represented partially, but forms a plate which extends in a plane. Such a printed circuit board is, for example, a component of a control device of a ventilation device for setting in motion a flow of air in a ventilation, heating and/or air conditioning installation. The function of this control device is to drive the speed of rotation of a propeller forming part of the ventilation device, by controlling the voltage or the current sent to an electric motor driving the rotation of the propeller.

The printed circuit board 1 is formed by an electrically insulating substrate 10, on which one or more electrically conductive tracks 2 are formed.

This printed circuit board 1 comprises a first face 3 and a second face 4 opposite the first face relative to the body of the printed circuit board.

According to an exemplary embodiment, the printed circuit board 1 comprises at least one hole 5, such a hole being a through hole, that is to say emerging in the first face 3 and in the second face 4.

The first face 3 of the printed circuit board 1 can bear electronic components 11, in particular power components which dissipate calories and for which cooling must be ensured to guarantee them a level of reliability compatible with an application in the motor vehicle field. These components which give off calories are, for example, transistors, notably of MOSFET type, but they can also be capacitors or shunts. The first face 3 can of course receive other electronic components which participate for example in implementing the driving or protection of the electric motor.

The hole or holes 5 receive a calorie conducting means 6. According to the embodiment of FIG. 1, this calorie conducting means is produced by thermal vias, preferably filled with a heat conducting material. In other words, the inner wall of the substrate 10 which bounds the hole 5 is metalized, so as to form a thermal drain which extends from the first face 3 to the second face 4 of the printed circuit board 1. According to a variant, the central area of the hole surrounded by the metalized part 7 can be free, thus forming a space. According to another alternative, the central area of the hole can be filled with a material, for example copper or the material used for the brazing of the electronic component 11.

One end of the metalized holes extends in the plane of the second face 4 and can thus be licked by a flow of air. In the two cases described above, the metalized part or parts 7 form a thermal drain which conducts the calories generated by the electronic component toward the flow of air, so as to dissipate them directly or indirectly therein.

According to the representation of FIG. 1, the calorie conducting means 6 is a set of thermal vias formed by the metalized part 7 of the holes 5, preferentially filled with a heat conducting material.

The metalized part 7 of the hole 5 is, for example, contained in the thickness of the printed circuit board 1 and it is connected on the side of the first face 3 to the conductive track 2 which runs on the first face 3. According to this variant, the electronic component 11 which gives off calories is not installed directly above the holes 5. On the contrary, the latter is situated away from the holes and the electrically conductive track 2 drains the calories from the electronic component 11 toward the metalized part or parts 7 of the holes 5. It will be understood here that an outer perimeter of the electronic component 11 delimits, on the first face 3 a first expropriation 12, whereas the hole or the plurality of holes 5, which contains the calorie conducting means 6, delimits a second expropriation 8 on the first face 3, the first expropriation 12 and the second expropriation 8 being separated by a non-zero distance, referenced 13 in FIG. 1. The first expropriation 12 is an area of the first face 3 delimited by a projection of the electronic component 11, at right angles to a plane in which the first face 3 of the printed circuit board 1 is inscribed. The second expropriation 8 is an area of the first face 3 occupied by the hole 5. In the case of a plurality of holes 5, the second expropriation 8 is delimited by a periphery surrounding the plurality of holes 18, measured in the plane of the first face 3.

Opposite the electrically conductive track 2, the metalized part 7 of the holes 5 ends in the plane of the second face 4, and a heat sink 9 is secured onto the printed circuit board 1 by brazing.

The heat sink 9 is preferentially at least partially facing the calorie conducting means 6. Such a heat sink 9 begins from the second face 4 and ends in a channel in which the flow of air circulates.

According to an exemplary embodiment not illustrated, this heat sink 9 is formed by a bar 14 secured by a braze onto the second face 4, for example at least partially facing the calorie conducting means 6, that is to say at least partially facing the second expropriation 8.

According to FIG. 1, the heat sink 9 can also comprise a base 16 onto which the bar 14 is fixed. The base 16 is then brazed by a braze 15 against the second face 4, at the level of the end of the metalized parts 7 formed in the holes 5.

To simplify FIGS. 2 to 4, the metalized parts 7 and the holes 5 have been represented symbolically, by strips. It is nevertheless clear that the technical content of the embodiment described above and illustrated in FIG. 1 can be transposed to any one of the embodiments illustrated in FIGS. 2 to 4, particularly with regard to the structure of the calorie conducting means 6.

FIG. 2 shows a first variant of the invention close to that represented in FIG. 1. The differences will be detailed hereinbelow and reference will be made to the description of FIG. 1 for the identical elements.

One difference lies in the positioning of the electronic component 11 likely to give off calories. Whereas, in FIG. 1, such a component is at a distance from the hole or holes, here the electronic component 11 is secured, notably by a braze, onto the first face 3 above the plurality of holes 5, that is to say above the calorie conducting means 6. In other words, an outer perimeter of the electronic component 11 delimits the first expropriation 12 on the first face 3. This first expropriation 12 is superposed on the second expropriation 8 delimiting the periphery surrounding the plurality of holes 5. The invention covers the case shown in this figure where the first expropriation 12 is totally superposed on the second expropriation 8, the latter covering a larger area than the area covered by the first expropriation.

The invention also covers the case where the first expropriation 12 is superposed at least partially with the second expropriation 8. In other words, the invention covers the situation where the electronic component 11 is entirely arranged above the plurality of holes 5, but it also covers the case where the electronic component 11 only partially overlaps the plurality of holes 5. The variant of this figure also comprises a heat sink 9, for example, identical to that of FIG. 1.

The second variant of the invention is represented in FIG. 3. The printed circuit board 1 receives a calorie conducting means 6 identical to that of FIGS. 1 or 2. On the other hand, the heat sink 9 has a different form. Indeed, the latter passes right through the printed circuit board 15, level with the calorie conducting means 6, for example at the center thereof. The bar 14 then has a free first end which emerges in the flow of air and a second end capped by a head 17 formed of a piece with the bar 14. The head 17 forms a flat which is secured onto the first face 3 by a braze 18 above the calorie conducting means 6.

The variant of FIG. 4 is close to that of FIG. 3. The difference will be detailed hereinbelow and reference will be made to the description of FIG. 3 for the identical elements. The difference lies in the way that the heat sink 9 is secured onto the calorie conducting means 6.

The heat sink 9 comprises the bar 14 capped by the head 17 identical to the variant of FIG. 3. The head 17 is not brazed onto the calorie conducting means 6 on the first face 3. A braze 15 is produced between the bar 14 and the calorie conducting means 6 on the second face 4 of the printed circuit board 1. The heat sink 9 then bears by its head 17 on a first end of the calorie conducting means 6, and is secured thereto through the braze 15 produced on the second face 4.

The second variant and the third variant of the invention employ a heat sink 9 which has a head 17, the latter jutting, in other words protruding, from the plane of the first face 3 between the electronic components secured onto this first face 3. The head contributes to picking up the calories generated by the electronic components to drain them toward the bar 14 licked by the flow of air.

The printed circuit board 1 described in the above variants can comprise a plurality of holes 5 and/or a plurality of identical calorie conducting means 6 and a plurality of identical heat sinks 9.

According to another variant, the printed circuit board 1 according to the present invention can comprise a combination of calorie conducting means 6 and of heat sinks 9 produced according to at least two variants explained above.

It will be noted that the heat sink 9 according to any one of the variants described above is advantageously made of an aluminum alloy or preferentially of copper.

It will be noted also that, preferentially, the printed circuit board 1 is provided under the second face 4 and/or on the first face 3 with a copper plane so as to allow various components to be brazed, and in particular

FIG. 5 illustrates an exemplary application of the printed circuit board 1 according to the invention in a ventilation device 19. Such a ventilation device comprises a support 20 inside which is housed an electric motor 21.

The electric motor 21 drives the rotation of a propeller 22 consisting of a bowl 23 represented by a broken line in this figure. This bowl forms a propeller driving means, since a shaft from the motor is linked to this bowl 23. Such a bowl is, for example, solid, in that its wall has no openings. According to another alternative, such a bowl 23 has a plurality of openings.

On the periphery of such a bowl 23, a plurality of blades 24 extend in a direction parallel to a direction of extension of the motor shaft. The end of each blade is joined by a band 25. Such a propeller 22 thus forms a squirrel cage propeller, otherwise called radial turbine.

Opposite the propeller 22 relative to the electric motor 21, there is the control device 26 whose function is to drive the speed of rotation of the propeller 22 by controlling the voltage or the current sent to the electric motor 21. Such a control device 26 is installed against the support 20 so as to be able to be exposed to the flow of air generated by the propeller 22, the control device being covered by a cap 27 so as to limit the ingress of foreign bodies into the portion of the ventilation device where the control device 26 is installed.

The support 20 comprises an opening 28 in which the flow of air set in motion by the propeller 22 can circulate, such a flow of air being represented schematically by two symbols referenced 29 and 30. Such an opening 28 is bordered laterally by at least one first wall 31, and advantageously by a second wall 32, one and/or the other of these walls being able to be secured to the printed circuit board 1. It will thus be understood that the flow of air 29, 30 is channeled by the support 20 and at least one and/or the other of the first and second walls referenced 31 and 32.

This channel is also delimited by the control device 26. More precisely, this channel is delimited by the printed circuit board 1 forming the control device 26.

The portion of the printed circuit board 1 which closes the channel for circulation of the flow of air 29, 30, in combination with the first wall 31 and the second wall 32, forms a part of said board in which are formed the hole or holes 5, the calorie conducting means 6 and the heat sink or sinks 9, as detailed with reference to FIGS. 1 to 4.

The second face 4 of the printed circuit board 1 is divided on the one hand into a part 33 of printed circuit board 1 licked by the flow of air 29, 30 circulated by the propeller 22, and on the other hand into an area 34 not exposed to the flow of air generated by the propeller 22. The one or more calorie conducting means 6 and the heat sink or sinks 9 are formed in the part 33, and are absent from the area 34.

The division between the part 33 of the printed circuit board 1 and the area 34 of this same board is organized by the first wall 31, and advantageously by the second wall 32. It will therefore be understood that the second face 4 which is located above the part 33 of the printed circuit board 1, which comprises at least calorie conducting means 6 and a heat sink 9, is licked by the flow of air 29, 31, so as to cool it and, correlatively, so as to cool the electronic components 11 which give off calories.

Such a part 33 of the printed circuit board 1 forms a support for the electrically conducted tracks. In other words, a plurality of electrically conductive tracks runs on the second face 4 licked by the flow of air and they are arranged in such a way as to limit the risk of short circuit between two electrically conductive tracks. Such an arrangement is, for example, a minimum distance separating the electrically conductive tracks which run on the part 33 licked by the flow of air. According to an exemplary embodiment, such a distance is, for example, 1.5 mm minimum.

According to one exemplary embodiment, the area 34 can comprise at least one electronic component 35 secured onto the second face 4 which extends in the area 34. This area also comprises a plurality of electrically conductive tracks not requiring an arrangement to avoid the short circuits since this area 34 is insulated from the circulating flow of air 29, 30, notably by virtue of the presence of the first wall 31 which is pressed against the second face 4, for example, at right angles to the plane of extension of the printed circuit board 1.

1. A cooling device for a printed circuit board, comprising:
a printed circuit board provided with at least one face or first face and at least one heat sink element brazed onto said at least one face of the printed circuit, said at least one heat sink element configured to be arranged in a flow of refrigerant.

2. The cooling device as claimed in claim 1, wherein said printed circuit board comprises two faces.

3. The cooling device as claimed in claim 2, further comprising at least one hole passing through said printed circuit board from one of the two faces to the other of the two faces, said one heat sink element being arranged facing said at least one through hole.

4. The cooling device as claimed in claim 3, in which said at least one through hole comprises an inner surface covered with a metallic substance.

5. The cooling device as claimed in claim 3, further comprising a plurality of holes passing through said printed circuit board.

6. The cooling device as claimed in claim 5, in which the printed circuit board is provided with an electronic component.

7. The cooling device as claimed in claim 6, in which an outer perimeter of the electronic component delimits a first expropriation on the first face, the plurality of holes delimits a second expropriation on the first face, the first expropriation and the second expropriation being separated by a non-zero distance.

8. The cooling device as claimed in claim 5, in which an outer perimeter of the electronic component delimits a first expropriation on the first face, the plurality of holes delimits a second expropriation on the first face, the first expropriation and the second expropriation being at least partially superposed.

9. The cooling device as claimed in claim 1, in which the at least one heat sink element comprises a head forming a bearing abutment against the printed circuit board.

10. A ventilation device of a ventilation installation of a motor vehicle interior, comprising:
a propeller generating a flow of air and suitable for being driven by an electric motor; and
a cooling device as claimed in claim 1.
